(19) United States
(12) Patent Application Publication
(10) Pub. No.: US 2014/0134852 A1
(43) Pub. Date: May 15, 2014

(54) METHOD AND APPARATUS FOR FORMING DIELECTRIC FILM OF LOW-DIELECTRIC CONSTANT AND METHOD FOR DETACHING POROGEN

(71) Applicant: Tokyo Electron Limited, Minato-ku (JP)

(72) Inventors: Yusaku IZAWA, Kurokawa-gun (JP); Masaki NARUSHIMA, Tsukuba City (JP)

(73) Assignee: TOKYO ELECTRON LIMITED, Minato-ku (JP)

(21) Appl. No.: 14/081,485

(22) Filed: Nov. 15, 2013

(30) Foreign Application Priority Data
Nov. 15, 2012 (JP) 2012-251106

(51) Int. Cl. H01L 21/02

(52) U.S. Cl. CPC H01L 21/02348; H01L 21/02203; H01L 21/02227; H01L 21/02164
USPC 438/800; 250/453.11

(57) ABSTRACT

A method for forming a porous low-k film having an Si—O structure includes irradiating infrared light upon a film including a material having an Si—O structure, and irradiating ultraviolet light upon the film including the material having the Si—O structure such that a porous low-k film including the material having the Si—O structure is formed. The irradiating of the infrared light has an irradiation period of infrared light which is set shorter than an irradiation period of ultraviolet light in the irradiating of the ultraviolet light.

### CROSS-REFERENCE TO RELATED APPLICATIONS

The present application is based upon and claims the benefit of priority to Japanese Patent Application No. 2012-251106, filed Nov. 15, 2012, the entire contents of which are incorporated herein by reference.

### BACKGROUND OF THE INVENTION

1. Field of the Invention

The present invention relates to a method and an apparatus for forming a low-k film on a substrate and a method for detaching a porogen.

2. Description of Background Art

In a semiconductor device such as a complementary metal oxide semiconductor (CMOS) device, copper (Cu) having a low electric resistance is usually employed as a wiring material for a fast processing. However, unlike aluminum (Al) which is widely employed in the art, it is difficult to apply plasma etching to copper. In this regard, when copper is used as a wiring material, a dual damascene technique is applied, in which a via hole or a trench matching a wiring is formed on an insulation film through etching in advance, and copper is buried in the trench through electroplating.

In a semiconductor device developed in recent years, the wiring is densely arranged to the point that crosstalk is generated between neighboring wirings. For alleviating the crosstalk, a low-dielectric insulation film (hereinafter referred to as a “low-k film”) is employed as an interlayer insulation film for lowering a dielectric constant of the insulation film interposed between the wirings (for example, refer to JP 2005-236285 A). As the low-k film, a porous low-k film is employed. The porous low-k film is formed by forming a SiOCH film containing a porogen, which is a hydrocarbon having a large molecular weight, through a plasma-enhanced chemical vapor deposition (PECVD) technique or a spin-on dielectric (SOD) technique and detaching multiple porogens from the SiOCH film to form pores in the film. The entire contents of this publication are incorporated herein by reference.

### SUMMARY OF THE INVENTION

According to one aspect of the invention, a method for forming a porous low-k film having an Si—O structure includes irradiating infrared light upon a film including a material having an Si—O structure, and irradiating ultraviolet light upon the film including the material having the Si—O structure such that a porous low-k film including the material having the Si—O structure is formed. The irradiating of the infrared light has an irradiation period of infrared light which is set shorter than an irradiation period of ultraviolet light in the irradiating of the ultraviolet light.

According to another aspect of the invention, an apparatus for forming a low-k film includes a holding device which holds a substrate on which a film including a material having an Si—O structure is formed, an infrared light emitting device which irradiates infrared light upon the film including the material having the Si—O structure formed on the substrate held by the holding device, an ultraviolet light emitting device which irradiates ultraviolet light upon the film including the material having the Si—O structure formed on the substrate held by the holding device, and a control device which controls the infrared light emitting device and the ultraviolet light emitting device such that an irradiation period of infrared light by the infrared light emitting device is shorter than an irradiation period of ultraviolet light by the ultraviolet light emitting device.

According to yet another aspect of the invention, a method for detaching a porogen, includes irradiating infrared light upon a material having a structure which includes CₓH_{y} in a bonding structure, and irradiating ultraviolet light upon the material having the structure which includes the CₓH_{y} in the bonding structure such that the CₓH_{y} in the bond structure is detached from the material having the structure which includes the CₓH_{y} in the bonding structure. The irradiating of the infrared light has an irradiation period of infrared light which is set shorter than an irradiation period of ultraviolet light in the irradiating of the ultraviolet light.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a structure of a curing treatment apparatus as an apparatus for forming a low-k film (low-dielectric constant film) according to an embodiment of the present invention;

FIG. 2 is a cross-sectional view schematically illustrating a structure of a semiconductor device having a low-k film formed by the curing treatment apparatus of FIG. 1;

FIG. 3 is a flowchart illustrating curing treatment in a method for forming a low-k film according to an embodiment of the present invention;

FIGS. 4A to 4C are diagrams illustrating a transition from a SiOCH film to a low-k film in the curing treatment of FIG. 3;

FIG. 5 is a diagram illustrating a temperature profile of the SiOCH film in spike annealing;

FIG. 6 is a flowchart illustrating a first modification of the curing treatment in the method for forming the low-k film according to the embodiment of the present invention;

FIG. 7 is a flowchart illustrating a second modification of the curing treatment in the method for forming the low-k film according to the embodiment of the present invention;

FIGS. 8A and 8B are graphs illustrating a component analysis result obtained by performing Fourier transform infrared spectroscopy (FTIR) on the low-k films of Example 1 and Comparative Example 1;

FIGS. 9A and 9B are graphs illustrating component analysis results obtained by performing FTIR on the low-k films of Example 2 and Comparative Example 2;

FIG. 10 is a graph illustrating measurement results of a refractive index and a film shrinkage factor of the low-k film of Examples 3 and 4 and Comparative Example 3; and

FIG. 11 is a graph illustrating measurement results of sheet resistances of silicon substrates of Example 5 and Comparative Examples 4 to 9.

### DETAILED DESCRIPTION OF THE EMBODIMENTS

The embodiments will now be described with reference to the accompanying drawings, wherein like reference numerals designate corresponding or identical elements throughout the various drawings.

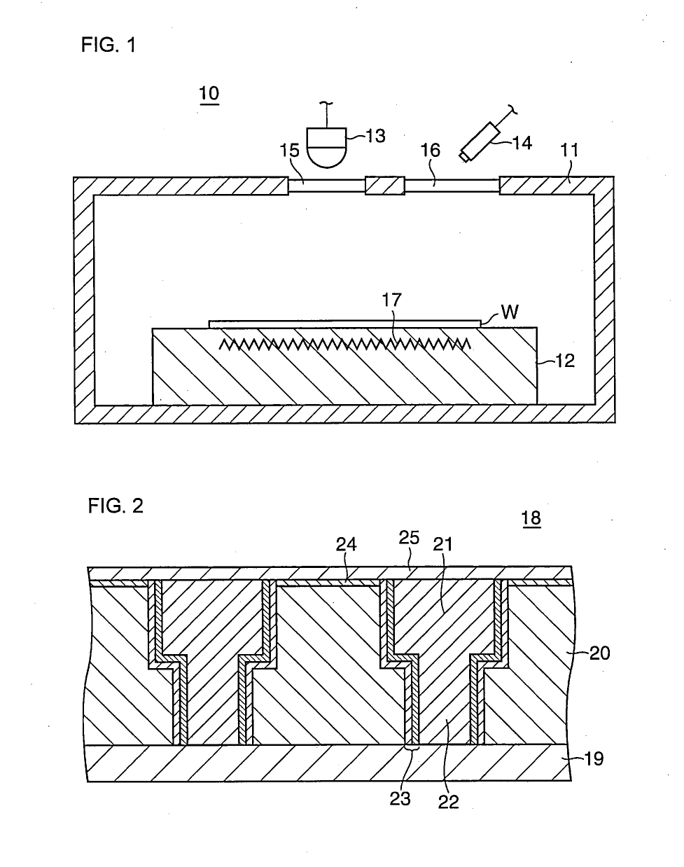

FIG. 1 is a cross-sectional view schematically illustrating a structure of the curing treatment apparatus as an apparatus for forming a low-k film according to an embodiment of the present invention.

Referring to FIG. 1, the curing treatment apparatus 10 includes: a chamber 11 structured to accommodate a wafer (W) having a surface where a SiOCH film (a film having an Si—O structure) is formed through a plasma-enhanced chemical vapor deposition (PECVD) method or a spin-on dielectric (SOD) method; a stage 12 where the wafer (W) is placed; an ultraviolet (UV) lamp 13 (ultraviolet light emitting unit) arranged outside the chamber 11 to face the stage 12; and an infrared laser (IR) light emitter 14 (infrared light laser emitting unit) arranged outside the chamber 11 to face the stage 12. A heater 17 is integrated into the stage 12.

A window 15 is fitted to a part of a ceiling portion of the chamber 11 facing the UV lamp 13 so that the ultraviolet light emitted from the UV lamp 13 transmits through the window 15 and arrives at a wafer W placed on the stage 12. The UV lamp 13 may be, for example, a direct current (DC) lamp or a pulse lamp. Specifically, the UV lamp 13 may be, for example, a heavy hydrogen lamp, a mercury lamp, a metal-halide lamp, or a xenon lamp. In the UV lamp 13, the ultraviolet light is generated, for example, from a microwave source, an arc discharge, a dielectric barrier discharge, or electron collision. An output power density of the ultraviolet light is set at approximately 0.1 to 2000 mW/cm², and a wavelength of the ultraviolet light is set at approximately 100 to 600 nm. Since the UV lamp 13 emits the ultraviolet light across a wide range, the ultraviolet light can be irradiated at the entire surface of the wafer W.

Instead of the UV lamp 13, an ultraviolet light-emitting diode (UVLED) or an ultraviolet laser light emitter may also be employed. The ultraviolet light emitter may include a light emitter capable of emitting a semiconductor laser (diode), a (nitrogen) gas laser, a third harmonic generation Nd:YAG laser, or a copper vapor laser.

A window 16 is also fitted to a part of the ceiling portion of the chamber 11 facing the infrared laser light emitter 14 so that the infrared laser light emitted from the infrared laser light emitter 14 transmits through the window 16 and arrives at the wafer (W) placed on the stage 12. The infrared laser light emitter 14 includes a carbon gas laser oscillator in which a carbon dioxide (CO₂) is used as a medium. The output power density of the infrared laser light is set at approximately 5000 W/cm² at maximum, and a wavelength of the infrared laser light is set at approximately 1 to 25 μm. While the infrared laser light emitter 14 irradiates the infrared laser light condensed by a condensing lens at a part of the wafer (W), an orientation angle can change so that the condensed infrared laser light can be irradiated at the surface of the wafer (W).

It is also an option to use a semiconductor laser (diode), a YAG laser, YVO₄ laser or a Yb-fiber laser instead of the carbon laser oscillator.

The curing treatment apparatus 10 applies curing treatment to the SiOCH film formed on the wafer (W) to form a low-k film 20. In the curing treatment, the SiOCH film of the wafer (W) is heated by the infrared laser light, and a porogen is detached. In addition, a Si—O bond inside the SiOCH film is reinforced by the ultraviolet light.

FIG. 2 is a cross-sectional view schematically illustrating a structure of the semiconductor device having the low-k film formed by the curing treatment apparatus of FIG. 1.

Referring to FIG. 2, the semiconductor device 18 includes: a low-k film 20 formed on the silicon substrate 19; a copper wire 21 or copper via 22 formed on the low-k film 20 using a dual damascene method; a barrier layer 23 interposed between the low-k film 20 and the copper wire 21 or copper via 22; a hard mask layer 24 formed on the low-k film 20; and a stopper layer 25 formed on the hard mask layer 24 and the copper wire 21. The silicon substrate 19 is provided with an active element such as MOSFET (not illustrated) and a wiring used to drive the active element. In addition, multiple low-k films 20 may also be deposited on the silicon substrate 19.

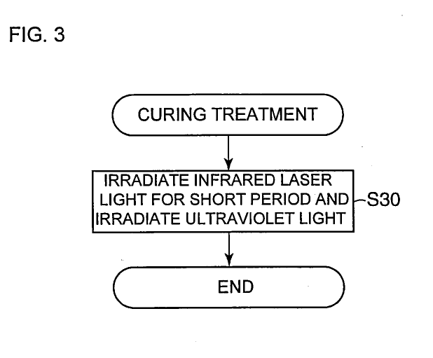

The low-k film 20 is formed by applying the curing treatment of FIG. 3 to the SiOCH film formed on the wafer (W) as described below. The copper wire 21 or the copper via 22 is formed by forming a via hole or a wiring trench in the low-k film 20 through etching, embedding copper in the via hole or the wiring trench through sputtering or electroplating, and removing excessive copper from the via hole or the wiring trench through chemical mechanical polishing (CMP).

The barrier layer 23 is made of a metal layer, a metal nitride layer, and a combination thereof. In addition, a portion of the barrier layer 23 making contact with the low-k film 20 may be made of a metal nitride film, and a portion of the barrier layer 23 making contact with the copper wire 21 or the copper via 22 may be made of a metal layer.

For example, the metal nitride film making contact with the low-k film 20 is made of a tantalum nitride (TaN) or a titanium nitride (TiN), and the metal layer making contact with the copper wire 21 or the copper via 22 is made of, for example, tantalum (Ta), titanium (Ti), ruthenium (Ru), or rhenium (Re).

In order to obtain a structure related to both a low dielectric constant and film strength of the low-k film 20, minute porogens are detached from the SiOCH film. To detach minute porogens, the SiOCH film is heated for a long time. However, in the semiconductor device 18, films or structures other than the low-k film 20 may be adversely affected by heating for such a long period.

It was determined that each porogen can be detached from the SiOCH film and adverse effects caused by heating films or structures other than the SiOCH film can be prevented by applying the curing treatment to the SiOCH film and heating the SiOCH film to a high temperature of, for example, 500° C. or higher for a short period of, for example, 2 seconds to form the low-k film 20.

It is difficult to clearly describe why porogens can be detached by heating the SiOCH film to a temperature of 500° C. or higher even for a short period. However, as a result of observing a process of forming the low-k film 20 through the curing treatment, the inventors analyzed that, while the SiOCH film is heated to a vicinity of 400° C., it is difficult to detach each porogen because each porogen is not highly active, and a binding such as a Si—O—Si bond of the SiOCH film that binds each porogen has not loosened much, while once the SiOCH film is heated to 500° C. of higher, each porogen becomes highly active, and a binding of the Si—O—Si bond of the SiOCH film that binds each porogen is loosened so that each porogen is easily detached.

FIG. 3 is a flowchart of the curing treatment in a method for forming the low-k film according to an embodiment of the present invention. This curing treatment is conducted after the SiOCH film is formed on the silicon substrate 19 of the wafer (W).

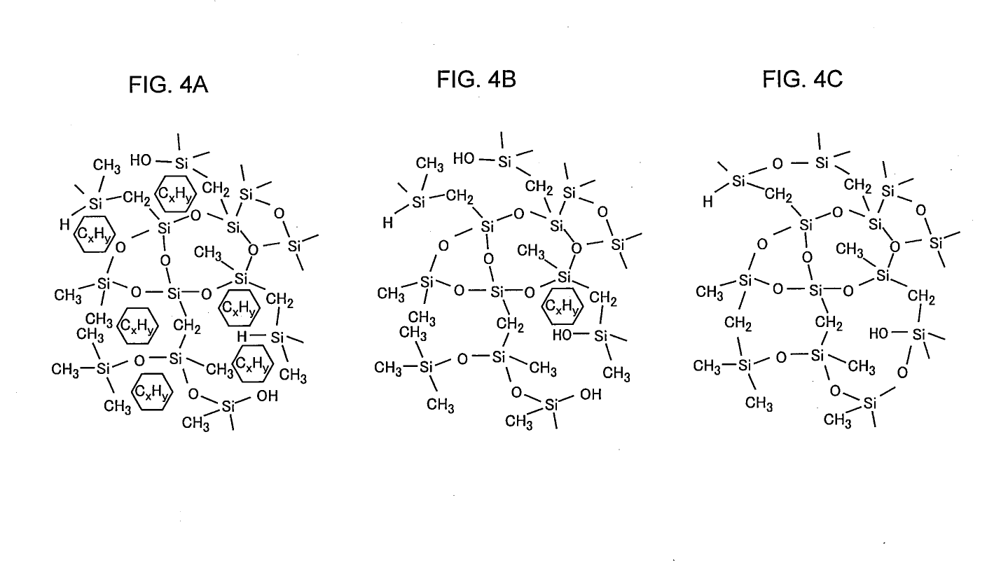

In a film formation apparatus separate from the curing treatment apparatus 10, a wafer (W) having a SiOCH film containing multiple minute porogens on the silicon substrate 19 is introduced into the inside of the chamber 11 of the curing treatment apparatus 10 and is placed on the stage 12. The SiOCH film formed by the film formation apparatus has a structure in which multiple silicon atoms (Si) linking to a hydrocarbon group or a hydroxyl group are bonded to each other by interposing an Si—O bond or an Si—CH₂ bond, and multiple porogens (CₓH_{y}) are interposed between such bond structures as illustrated in FIG. 4A.

Then, the wafer (W), specifically the SiOCH film, is heated to a high temperature (hereinafter, referred to as a “base temperature”) (first temperature) of, for example, 360° or higher but 430° C. or lower, preferably 360° C. or higher but 380° C. or lower using the heater 17, and ultraviolet light is irradiated at the SiOCH film using the UV lamp 13 (ultraviolet light irradiation step) (step S30). In addition, infrared laser light is irradiated at the SiOCH film from the infrared laser light emitter 14, and the infrared laser light is irradiated at the surface of the SiOCH film (infrared light irradiation step) (step S30).

The heating using the heater 17 and the irradiation of ultraviolet light are continuously performed for a relatively long period, for example, 180 seconds. In addition, in the irradiation of the infrared laser light, an irradiation period of the infrared laser light for each part of the SiOCH film is set for a short period, for example, 2 seconds or shorter, preferably, 0.5 seconds or shorter. However, a vibration is generated in each Si—O bond of the SiOCH film by the infrared laser light to generate instantaneous heating, so that each part of the SiOCH film is heated to a temperature higher than a base temperature (hereinafter, referred to as a “spike temperature”) (second temperature), for example, of 500° C. or higher but 700° C. or lower, preferably 550° C. or higher but 700° C. or lower, and more preferably 600° C. or higher but 700° C. or lower.

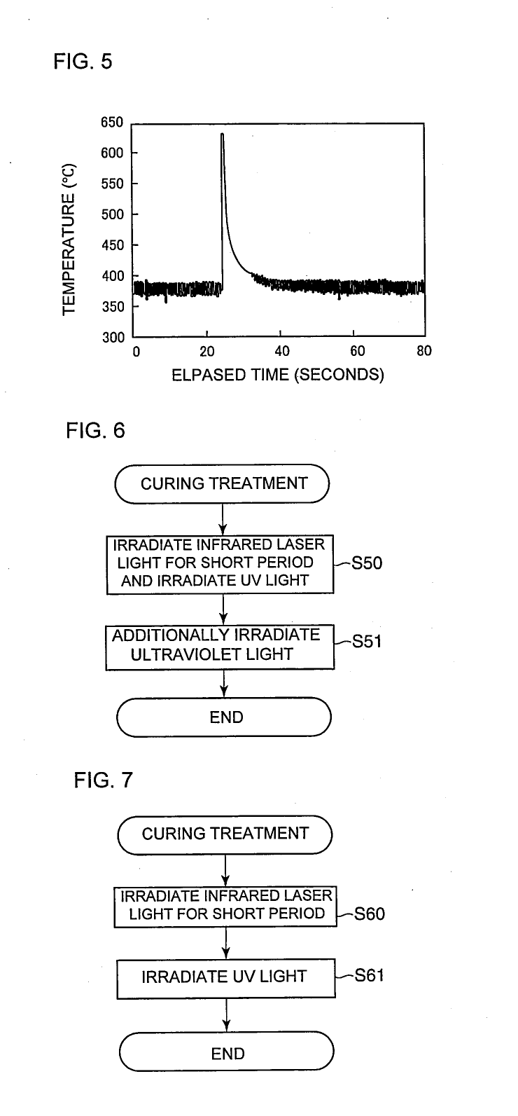

The high-temperature and short-period heating based on infrared laser light irradiation described above is called spike annealing, and a temperature profile of the SiOCH film in the spike annealing is illustrated in FIG. 5.

The temperature profile of FIG. 5 may be implemented through high-temperature and short-period heating (flash lamp annealing) by instantaneously irradiating infrared light from the infrared light lamp as well as spike annealing by irradiating infrared laser light. The infrared lamp can emit infrared light across a wide range once. Therefore, unlike spike annealing, in the flash lamp annealing, infrared light is not irradiated, and the annealing can be performed for a shorter period.

In step S30, once the SiOCH film is heated to 500° C. or higher even for a short period by irradiating infrared laser light, motions of each porogen are activated and instantaneously detached from the aforementioned bond structure (refer to FIG. 4B). As a result, multiple pores are formed having a size corresponding to each porogen detached from the SiOCH film. In addition, as ultraviolet light is irradiated at the SiOCH film, the Si—O bond or the Si—CH₂ bond is reinforced (refer to FIG. 4C). Accordingly, the film strength of the SiOCH film is improved. As a result, a low-k film 20 with a structure containing multiple pores and having high film strength is obtained. Then, this process is completed.

In the curing treatment in FIG. 3, while infrared laser light is irradiated at the SiOCH film for a short period, the SiOCH film is heated to the spike temperature higher than the base temperature. Therefore, as the SiOCH film is heated to a sufficiently high temperature, each porogen is detached from the SiOCH film. Meanwhile, since the irradiation period of the infrared laser light at the SiOCH film is significantly shorter than the irradiation period of the ultraviolet light at the SiOCH film, the thermal budget of the SiOCH film does not increase. As a result, adverse effects caused by heating are prevented from being generated in films other than the SiOCH film when each porogen is detached. In addition, fracture of the copper wire 21 and degradation of the sheet resistance of the silicon substrate 19 are prevented.

In the curing treatment of FIG. 3, the infrared laser light emitting unit emits infrared laser light at the surface of the SiOCH film of the wafer (W). Therefore, the SiOCH film is uniformly heated and porogens are thoroughly detached.

While embodiments of the present invention have been described above, the present invention is not limited to the aforementioned embodiments.

The curing treatment in the method for forming the low-k film according to the embodiment is not limited to the processing shown in FIG. 3. For example, as illustrated in FIG. 6, it is an option to continue irradiation of ultraviolet light at the SiOCH film (step S51) after heating the SiOCH film to the base temperature as illustrated in step S30 of FIG. 30, irradiating ultraviolet light at the SiOCH film using the UV lamp 13, and further irradiating infrared laser light at the surface of the SiOCH film (step S50) so as to finish the surface treatment of the SiOCH film using infrared laser light. In this case as well, porogens are each detached from the SiOCH film and the Si—O bond or the Si—CH₂ bond in the SiOCH film is further reinforced. Therefore, a low-k film 20 with a structure containing multiple pores and having high film strength is obtained.

Alternatively, as illustrated in FIG. 7, it is an option to first heat the SiOCH film to the base temperature, followed by surface scanning of the SiOCH film by the infrared laser light (step S60), and then to irradiate the ultraviolet light at the SiOCH film after the surface treatment of the SiOCH film is finished using the infrared laser light (step S61). That is, the short-period heating of the SiOCH film using the infrared laser light and the irradiation of ultraviolet light at the SiOCH film may be separately executed. In this case, the Si—O bond or the Si—CH₂ bond in the SiOCH film is reinforced after each porogen from the SiOCH film is detached. Naturally, the low-k film 20 with a structure containing multiple pores and having high film strength is obtained.

In the curing treatment of either of FIG. 6 or 7, the base temperature is set to, for example, 360° C. or higher but 430° C. or lower, and preferably, 360° C. or higher but 380° C. or lower, and the heating using the heater 17 is continuously performed, for example, for 180 seconds. However, the irradiation period of infrared laser light for each part of the SiOCH film is set to, for example, 2 seconds or shorter, and preferably, 0.5 seconds or shorter, and the spike temperature is set at, for example, 500° C. or higher but 700° C. or lower, preferably 550° C. or higher but 700° C. or lower, and more preferably, 600° C. or higher but 700° C. or lower.

In the method for forming the low-k film according to the present embodiment, a pure SiOCH film is employed as a film with an Si—O structure for applying the curing treatment. However, the film for applying the curing treatment is not limited to the pure SiOCH film and may include an SiOCH film containing some additives. In addition, a film having an Si—O structure containing porogens and capable of substituting the Si—OH bond or the Si—CH₃ bond with the Si—O bond when irradiated by ultraviolet light may be employed.

Also, by installing a storage medium that stores codes of a software program capable of implementing functionalities of the embodiments described above in a computer provided in the curing treatment apparatus 10 or the film formation apparatus, a CPU of the computer reads the program codes stored in the storage medium and executes the command.

In this case, the program codes read from the storage medium implement functionalities of the aforementioned embodiments, and the program codes and the storage medium that stores the program codes embody an embodiment of the present invention.

A storage medium may take any form, including but not limited to, a random access memory (RAM), a non-volatile (NV) RAM, a floppy disk (registered trademark), a hard disk, an optical-magnetic disk, optical disks such as CD−ROM, CD−R, CD−RW, and DVD (such as DVD−ROM, DVD−RAM, DVD−RW, and DVD+RW), a magnetic tape, a non-volatile memory card, and other ROMs as long as it can store the program codes. Alternatively, the program codes may be downloaded and supplied to the computer from a computer or database connected via the Internet, a commercial network, a local area network or the like.

By executing the program codes read by the computer, functionalities of the embodiments described above are implemented, and an operating system (OS) or the like operated on the CPU may execute a part or all of the processes in practice in response to the commands from the program in order to implement the functionalities of the embodiments described above.

The functionalities of the embodiments described above may also be embodied when the program codes read from the storage medium are written to a functionality expansion board inserted in a computer or a functionality expansion unit connected to a computer, and a CPU or the like provided in the functionality expansion board or the functionality expansion unit then executes a part or all of the processes in practice.

The program codes may have many forms such as an object code, a program code executed by an interpreter, and script data supplied to the OS.

### EXAMPLES

Hereinafter, examples according to the present invention will be described.

Influence on the low-k film caused by heating it for a short period to a spike temperature was examined.

Initially, in Example 1, a wafer (W) obtained by forming an SiOCH film on a silicon substrate 19 was prepared, and pressure inside a chamber 11 of a curing treatment apparatus 10 was set at 15 Torr. Then, the SiOCH film of the wafer (W) was heated to a base temperature of 380° C. for 180 seconds according to the curing treatment in FIG. 3, and ultraviolet light was irradiated at the SiOCH film. In addition, infrared laser light was irradiated at the surface of the SiOCH film to form a low-k film 20. An irradiation period of infrared laser light for each part of the SiOCH film was 0.14 seconds. However, each part of the SiOCH film was heated to 620° C. (spike temperature). That is, spike annealing was applied to the SiOCH film of Example 1 at a high temperature for a short period.

Next, in Comparative Example 1, a wafer (W) obtained by forming a SiOCH film on a silicon substrate 19 was prepared, and pressure inside a chamber of a curing treatment apparatus was set to 15 Torr. Then, a conventional curing treatment was applied for 300 seconds to form a low-k film. Specifically, the SiOCH film of the wafer (W) was heated to a base temperature of 435° C. using a heater 17, and ultraviolet light was irradiated at the SiOCH film to form the low-k film. Infrared laser light was not irradiated at each part of the SiOCH film.

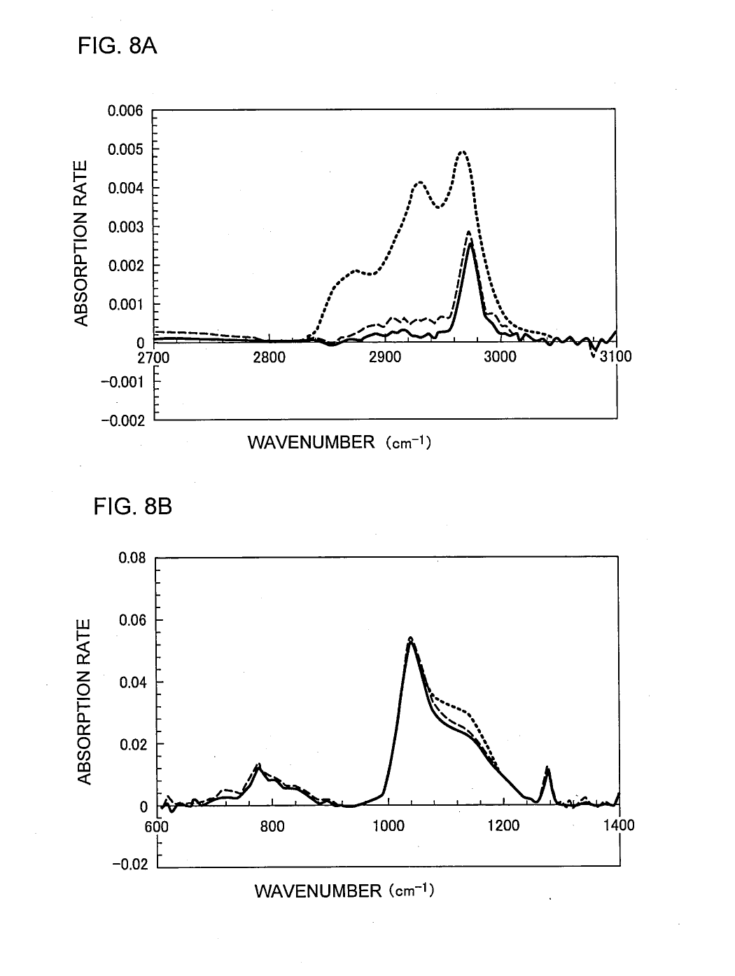

Then, a component of the low-k film 20 of Example 1 and a component of the low-k film of Comparative Example 1 were analyzed using a Fourier transform infrared spectroscopy (FTIR) analyzer, and the results are illustrated in the graphs in FIGS. 8A and 8B. For reference, a component of the SiOCH film before the curing treatment was also analyzed using the FTIR analyzer. In the graphs of FIGS. 8A and 8B, the solid line denotes the low-k film 20 of Example 1, the dotted line denotes the low-k film of Comparative Example 1, and the thin dotted line denotes the SiOCH film before the curing treatment.

A porogen absorbs infrared light having a wavenumber of 2850 to 2940 cm⁻¹ in the FTIR. However, as illustrated in FIG. 8A, it was observed that an infrared light absorption amount at a wavenumber of 2850 to 2940 cm⁻¹ in Example 1 is substantially zero, which is smaller than the infrared light absorption amount of Comparative Example 1 at the same wavenumber range. That is, in Comparative Example 1, it was observed that each porogen is not sufficiently detached from the SiOCH film even when the SiOCH film is heated to a temperature of 435° C. for a longer duration of 300 seconds. Meanwhile, in Example 1, it was found that each porogen is sufficiently detached when the SiOCH film is heated to a temperature of 620° C. for a significantly short period of 0.14 seconds.

From the aforementioned description, it was found that each porogen can be sufficiently detached when the SiOCH film is heated to the spike temperature (620° C. in Example 1) even through instantaneous heating.

The Si—CH₃ bond contributing to a low dielectric constant of the low-k film absorbs infrared light having a wavenumber of 1275 cm⁻¹ in the FTIR. However, as illustrated in the graph of FIG. 8B, the infrared light absorption amount at a wavenumber of 1275 cm⁻¹ between Example 1 and Comparative Example 1 was nearly equal. In addition, a network structure of the Si—O bond contributing to the film strength of the low-k film (in which multiple Si—O bonds are linked in a reticular shape) absorbs infrared light having a wavenumber of 1060 cm⁻¹ in the FTIR. However, as illustrated in the graph of FIG. 8B, the infrared light absorption amount at a wavenumber of 1060 cm⁻¹ was nearly equal between Example 1 and Comparative Example 1.

That is, it was found that a bonding state in the low-k film structure is not damaged if the heating is performed for a short period even at a high spike temperature. In addition, it was also found that the structure of the low-k film relating to the film strength and the dielectric constant are not affected.

Although not illustrated in the graphs of FIGS. 8A and 8B, a film shrinkage factor serving as an index of the film strength of the low-k film was 19.0% in Example 1 and 19.2% in Comparative Example 1. In addition, a refractive index serving as the dielectric constant of the low-k film was 1.3108 in Example 1 and 1.3148 in Comparative Example 1, which are not significantly different.

From the aforementioned description, it was found that the film strength or the dielectric constant of the low-k film between Example 1 and Comparative Example 1 is not different even when the base temperature of Example 1 is set at 380° C. and the base temperature of Comparative Example 1 is set at 435° C. Therefore, it was found that the temperature of the curing treatment of the low-k film is effectively lowered by applying spike annealing at a high temperature for a short duration.

Comparing the curing treatment period between Example 1 and Comparative Example 1, the curing treatment period is set for 180 seconds in Example 1 and 300 seconds in Comparative Example 1. That is, it was found that the curing treatment period can be reduced by applying spike annealing at a high temperature for a short period.

In Example 2, a wafer (W) obtained by forming a SiOCH film on a silicon substrate 19 was prepared, and pressure inside a chamber 11 of a curing treatment apparatus 10 was set at 15 Torr. Then, the SiOCH film of the wafer (W) was heated to a base temperature of 400° C. for 210 seconds according to the curing treatment of FIG. 3, and ultraviolet light was irradiated at the SiOCH film. In addition, infrared laser light was irradiated at the surface of the SiOCH film to form a low-k film 20. The irradiation period of infrared laser light for each part of the SiOCH film was 0.14 seconds. However, each part of the SiOCH film was heated to 600° C. (spike temperature). That is, spike annealing was applied to the SiOCH film of Example 2 at a high temperature for a short period.

Next, in Comparative Example 2, a wafer (W) obtained by forming an SiOCH film on a silicon substrate 19 was prepared, and pressure inside a chamber of a curing treatment apparatus was set at 3 Torr. Then, a curing treatment was applied for 300 seconds to form a low-k film. Specifically, the SiOCH film of the wafer (W) was heated to a base temperature of 420° C. using a heater 17 and through infrared light irradiation using an IR lamp, and ultraviolet light was irradiated at the SiOCH film to form the low-k film.

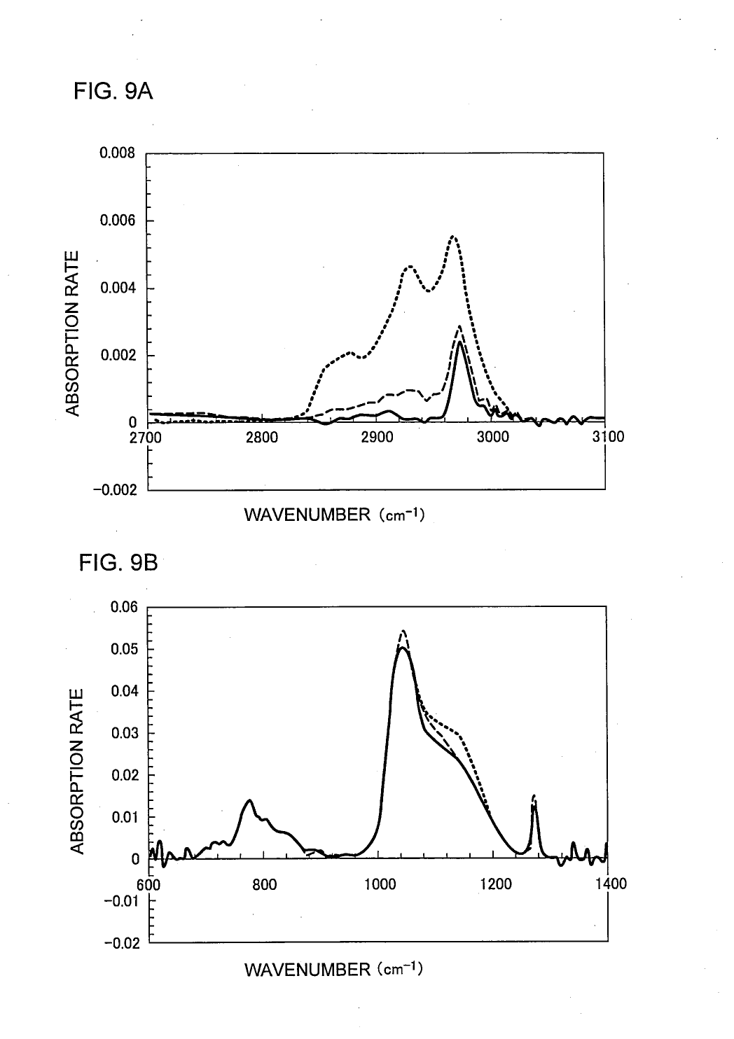

Then, a component of the low-k film 20 of Example 1 and a component of the low-k film of Comparative Example 1 were analyzed using a FTIR analyzer, and the results are shown in the graphs of FIGS. 9A and 9B. For reference, a component of the SiOCH film before the curing treatment was also analyzed using the FTIR analyzer. In the graphs of FIGS. 9A and 9B, the solid line denotes the low-k film 20 of Example 2, the dotted line denotes the low-k film of Comparative Example 2, and the thin dotted line denotes the SiOCH film before the curing treatment.

As shown in FIG. 9A, it was observed that the infrared light absorption amount at a wavenumber of 2850 to 2940 cm⁻1 in Example 2 is substantially zero, which is smaller than the infrared light absorption amount of Comparative Example 2 in the same wavenumber range. That is, in Comparative Example 2, it was observed that each porogen is not sufficiently detached from the SiOCH film even when the SiOCH film is heated to a temperature of 420° C. for a longer period of 300 seconds. Meanwhile, in Example 2, it was found that each porogen is sufficiently detached when the SiOCH film is heated to a temperature of 600° C. for a significantly short period of 0.14 seconds.

From the aforementioned description, similar to comparison between Example 1 and Comparative Example 1, it was found that each porogen can be sufficiently detached as the SiOCH film is heated to the spike temperature (600° C. in Example 2) even through instantaneous heating.

As illustrated in the graph of FIG. 9B, the infrared light absorption amounts at wavenumbers of 1275 cm⁻1 and 1060 cm⁻1 were nearly equal between Example 2 and Comparative Example 2. That is, similar to Example 1 and Comparative Example 1, it was found that a bonding state in the low-k film structure is not broken if the heating is performed for a short period even at a high spike temperature. In addition, it was also found that the film strength of the low-k film and the dielectric constant are not affected.

Although not illustrated in the graphs of FIGS. 9A and 9B, the film shrinkage factor was 18.1% in Example 2 and 17.5% in Comparative Example 2. Since the film shrinkage factor of Example 2 is higher while the film strength is also higher in Example 2, it was observed that the film strength of the low-k film is not lowered even at a high spike temperature if the curing treatment is performed for a short period. In addition, it was found that, since porogens are more effectively detached in Example 2 compared with Comparative Example 2 as described above, and a refractive index was 1.3081 in Example 2 and 1.3356 in Comparative Example 2, the refractive index of Example 2 is lower than that of Comparative Example 2, and the dielectric constant of Example 2 is also lower than that of Comparative Example 2 by approximately 0.1.

Next, influence on the film strength and the dielectric constant caused by applying spike annealing at a high temperature for a short period was examined in detail.

In Example 3, a wafer (W) obtained by forming an SiOCH film on a silicon substrate 19 was prepared, and pressure inside a chamber 11 of a curing treatment apparatus 10 was set at 15 Torr. Then, the SiOCH film of the wafer (W) was heated to a base temperature of 400° C. for 180 seconds, 360 seconds, and 540 seconds according to the curing treatment in FIG. 3, and ultraviolet light was irradiated at the SiOCH film. In addition, infrared laser light was irradiated at the surface of the SiOCH film to form a low-k film 20. An irradiation period of infrared laser light for each part of the SiOCH film was set for 0.28 seconds when the heating period to the base temperature was set for 180 seconds. The irradiation period of infrared laser light was set for 0.56 seconds when the heating period to the base temperature was set for 360 seconds. The irradiation period of infrared laser light was set to 0.84 seconds when the heating time to the base temperature was set to 540 seconds. In this case, each part of the SiOCH film was heated to 540° C. (spike temperature). That is, spike annealing was applied to the SiOCH film of Example 3 at a high temperature for a short period.

In Example 4, a wafer (W) obtained by forming a SiOCH film on a silicon substrate 19 was prepared, and pressure inside a chamber 11 was set at 15 Torr. Then, the SiOCH film was heated to a base temperature of 400° C. for the same period as that of Example 3 according to the curing treatment of FIG. 3, and ultraviolet light was irradiated at the SiOCH film. In addition, infrared laser light was irradiated at the surface of the SiOCH film to form a low-k film 20. The irradiation period of infrared laser light for each part of the SiOCH film was set for the same period as that of Example 3. In this case, each part of the SiOCH film was heated to 650° C. (spike temperature). That is, spike annealing was applied to the SiOCH film of Example 4 at a high temperature for a short period.

Next, in Comparative Example 3, a wafer (W) obtained by forming a SiOCH film on a silicon substrate 19 was prepared, and pressure inside a chamber of a curing treatment apparatus having an IR lamp capable of irradiating the entire surface of the wafer W was set at 15 Torr. Then, a curing treatment was applied for 180 seconds, 360 seconds and 540 seconds to form a low-k film. Specifically, by irradiating infrared light at the SiOCH film of the wafer (W) using a heater 17 and the IR lamp, the SiOCH film was heated to a base temperature of 400° C. Then, ultraviolet light was irradiated at the SiOCH film to form the low-k film.

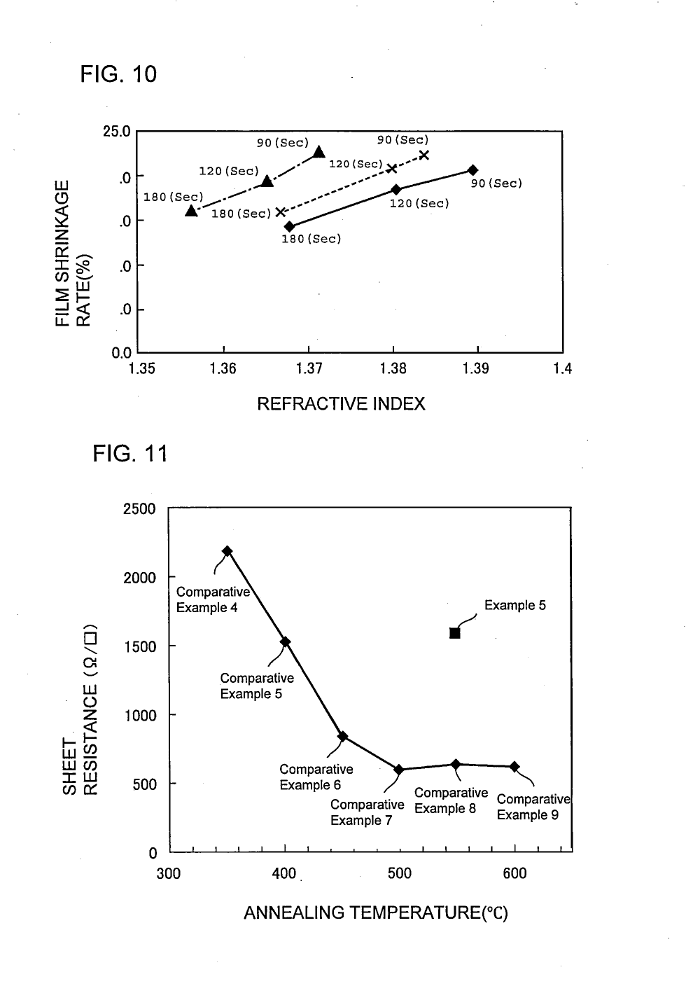

Then, film shrinkage factors (serving as an index of the film strength of the low-k film) and refractive indices (serving as an index of the dielectric constant of the low-k film) of the low-k films 20 of Examples 3 and 4 and Comparative Example 3 were measured. The results are illustrated in the graph in FIG. 10. In the graph in FIG. 10, the one-dotted chain line denotes the low-k film 20 of Example 3, the dotted line denotes the low-k film 20 of Example 4, and the solid line denotes the low-k film of Comparative Example 3.

In general, as the refractive index decreases, porogens are detached better, and the dielectric constant decreases. However, in the graph in FIG. 10, the refractive index of Example 3 is lowest, and the refractive index of Comparative Example 3 is highest. Therefore, it was found that, as the spike annealing is applied, porogens are detached easily, and the dielectric constant decreases. In addition, it was found that, as the spike temperature of the spike annealing increases, porogens are detached easily, and the dielectric constant decreases.

In general, as the film shrinkage factor increases, the Si—O bond is reinforced, and the film strength is improved. However, referring to the graph in FIG. 10, the film shrinkage factor of Example 3 is highest, and the film shrinkage factor of Comparative Example 3 is lowest. Therefore, it was found that, as the spike annealing is applied, the Si—O bond is reinforced, and the film strength is improved. It was also found that, as the spike temperature of the spike annealing increases, the Si—O bond is reinforced, and the film strength is improved.

Next, influence on the sheet resistance of the silicon substrate caused by the curing treatment was examined.

In Example 5, a wafer (W) was prepared, and phosphorus (P) was doped on the silicon substrate 19. Then, a silica (SiO₂) film was formed on the wafer (W), and an SiOCH film was formed on the silica film. Then, the SiOCH film of the wafer (W) was heated to a base temperature of 400° C., and infrared laser light was irradiated at the surface of the SiOCH film to form a low-k film 20. While the irradiation period of infrared laser light for each part of the SiOCH film was set to be 0.08 seconds, each part of the SiOCH film was heated to 550° C. (spike temperature). That is, spike annealing was applied to the SiOCH film of Example 5 at a high temperature for a short period.

Then, the silica film and the SiOCH film were removed from the wafer (W) and the sheet resistance of the exposed silicon substrate 19 was measured. The result is illustrated in the graph in FIG. 11.

Next, in Comparative Examples 4 to 9, a wafer was prepared, and phosphorous was doped on the silicon substrate 19 of the wafer (W). Then, a silica film was formed on the wafer (W), and a SiOCH film was formed on the silica film. Then, the SiOCH film of each wafer (W) was heated for 190 seconds to 350° C. (Comparative Example 4), 400° C. (Comparative Example 5), 450° C. (Comparative Example 6), 500° C. (Comparative Example 7), 550° C. (Comparative Example 8), and 600° C. (Comparative Example 9).

Then, the silica film and the SiOCH film were removed from each wafer (W), and the sheet resistance of the exposed silicon substrate 19 was measured. The results are shown in the graph of FIG. 11.

Referring to the graph of FIG. 11, it is confirmed that the sheet resistance of Example 5 is substantially equal to that of Comparative Example 5. Since the sheet resistance is an index of a thermal budget received by the silicon substrate 19, it is found that the thermal budget received by the silicon substrate 19 of Example 5 is substantially equal to that of Comparative Example 5.

That is, if the spike annealing is applied at a high temperature for a short period, the thermal budget does not increase. Therefore, it is found that adverse effects caused by heating the silicon substrate 19 in the curing treatment are prevented.

If the SiOCH film is heated for a longer period in order to detach multiple porogens from the SiOCH film, the amount of heat (thermal budget) received by the SiOCH film increases. For this reason, there may be an adverse effect caused by heating films or structures other than the low-k film, such as a wiring fracture or a decrease of the sheet resistance of the silicon substrate as an underlying layer.

In the method and apparatus for forming the low-k film and the method for detaching a porogen according to embodiments of the present invention, adverse effects caused by heating films or structures other than the Si—O structure film can be prevented.

In the method for forming a low-k film and the method for detaching a porogen according to an embodiment of the present invention, there is provided a method for forming a porous low-k film having an Si—O structure, including an infrared laser light irradiation step for irradiating infrared light, and an ultraviolet light irradiation step for irradiating ultraviolet light. In such a method, an irradiation period of the infrared light is set shorter than an irradiation period of the ultraviolet light.

According to an embodiment of the present invention, there is provided an apparatus for forming a low-k film, including an infrared light emitting unit structured to irradiate infrared light at an Si—O structure film formed on a substrate for a short period, and an ultraviolet light emitting unit structured to irradiate ultraviolet light at the Si—O structure film. In such an apparatus, an irradiation period of the infrared light emitting unit is set shorter than an irradiation period of the ultraviolet light emitting unit.

Obviously, numerous modifications and variations of the present invention are possible in light of the above teachings. It is therefore to be understood that within the scope of the appended claims, the invention may be practiced otherwise than as specifically described herein.

What is claimed is:

1. A method for forming a porous low-k film having an Si—O structure, comprising:
irradiating infrared light upon a film comprising a material having an Si—O structure; and
irradiating ultraviolet light upon the film comprising the material having the Si—O structure such that a porous low-k film comprising the material having the Si—O structure is formed,
wherein the irradiating of the infrared light has an irradiation period of infrared light which is set shorter than an irradiation period of ultraviolet light in the irradiating of the ultraviolet light.

2. The method for forming a porous low-k film according to claim 1, wherein the irradiating of the infrared light is 2 seconds or less.

3. The method for forming a porous low-k film according to claim 2, wherein the irradiating of the infrared light is 0.5 seconds or less.

4. The method for forming a porous low-k film according to claim 1, wherein the infrared light is irradiated upon the film such that the film comprising the material having the Si—O structure is heated to a temperature in a range of 500° C. or more and 700° C. or less.

5. The method for forming a porous low-k film according to claim 4, wherein the infrared light is irradiated upon the film such that the film comprising the material having the Si—O structure is heated to a temperature in a range of 550° C. or more and 700° C. or less.

6. The method for forming a porous low-k film according to claim 5, wherein the infrared light is irradiated upon the film such that the film comprising the material having the Si—O structure is heated to a temperature in a range of 600° C. or more and 700° C. or less.

7. The method for forming a porous low-k film according to claim 1, further comprising:
heating the film comprising the material having the Si—O structure to a first temperature prior to the irradiating of the infrared light,
wherein the infrared light is irradiated upon the film such that the film comprising the material having the Si—O structure is heated to a second temperature which is higher than the first temperature, and the irradiating of the infrared light has the irradiation period which is set shorter than a period of heating the film comprising the material having the Si—O structure to the first temperature.

8. The method for forming a porous low-k film according to claim 7, wherein the first temperature is in a range of 600° C. or more and 430° C. or less.

9. The method for forming a porous low-k film according to claim 8, wherein the first temperature is in a range of 360° C. or more and 380° C. or less.

10. The method for forming a porous low-k film according to claim 1, wherein the irradiating of the infrared light comprises irradiating infrared laser light generated by a carbon dioxide medium.

11. The method for forming a porous low-k film according to claim 2, wherein the infrared light is irradiated upon the film such that the film comprising the material having the Si—O structure is heated to a temperature in a range of 500° C. or more and 700° C. or less.

12. The method for forming a porous low-k film according to claim 2, further comprising:
heating the film comprising the material having the Si—O structure to a first temperature prior to the irradiating of the infrared light,
wherein the infrared light is irradiated upon the film such that the film comprising the material having the Si—O structure is heated to a second temperature which is higher than the first temperature, and the irradiating of the infrared light has the irradiation period which is set shorter than a period of heating the film comprising the material having the Si—O structure to the first temperature.

13. The method for forming a porous low-k film according to claim 3, further comprising:
heating the film comprising the material having the Si—O structure to a first temperature prior to the irradiating of the infrared light,
wherein the infrared light is irradiated upon the film such that the film comprising the material having the Si—O structure is heated to a second temperature which is higher than the first temperature, and the irradiating of the infrared light has the irradiation period which is set shorter than a period of heating the film comprising the material having the Si—O structure to the first temperature.

14. The method for forming a porous low-k film according to claim 4, further comprising:
heating the film comprising the material having the Si—O structure to a first temperature prior to the irradiating of the infrared light,
wherein the infrared light is irradiated upon the film such that the film comprising the material having the Si—O structure is heated to a second temperature which is higher than the first temperature, and the irradiating of the infrared light has the irradiation period which is set shorter than a period of heating the film comprising the material having the Si—O structure to the first temperature.

15. The method for forming a porous low-k film according to claim 5, further comprising:
heating the film comprising the material having the Si—O structure to a first temperature prior to the irradiating of the infrared light, wherein the infrared light is irradiated upon the film such that the film comprising the material having the Si—O structure is heated to a second temperature which is higher than the first temperature, and the irradiating of the infrared light has the irradiation period which is set shorter than a period of heating the film comprising the material having the Si—O structure to the first temperature.

16. An apparatus for forming a low-k film, comprising:
a holding device configured to hold a substrate on which a film comprising a material having an Si—O structure is formed;
an infrared light emitting device configured to irradiate infrared light upon the film comprising the material having the Si—O structure formed on the substrate held by the holding device;
an ultraviolet light emitting device configured to irradiate ultraviolet light upon the film comprising the material having the Si—O structure formed on the substrate held by the holding device; and
a control device configured to control the infrared light emitting device and the ultraviolet light emitting device such that an irradiation period of infrared light by the infrared light emitting device is shorter than an irradiation period of ultraviolet light by the ultraviolet light emitting device.

17. The apparatus for forming a low-k film according to claim 16, wherein the infrared light emitting device is configured to scan the infrared light over a surface of the substrate.

18. The apparatus for forming a low-k film according to claim 16, wherein the infrared light emitting device is configured to irradiate the infrared light comprising an infrared laser light generated by a carbon dioxide medium.

19. The apparatus for forming a low-k film according to claim 17, wherein the infrared light emitting device is configured to irradiate the infrared light comprising an infrared laser light generated by a carbon dioxide medium.

20. A method for detaching a porogen, comprising:
irradiating infrared light upon a material having a structure which includes CₓH_{y} in a bonding structure; and
irradiating ultraviolet light upon the material having the structure which includes the CₓH_{y} in the bonding structure such that the CₓH_{y} in the bond structure is detached from the material having the structure which includes the CₓH_{y} in the bonding structure, wherein the irradiating of the infrared light has an irradiation period of infrared light which is set shorter than an irradiation period of ultraviolet light in the irradiating of the ultraviolet light.
